(19) United States
(12) Patent Application Publication
(10) Pub. No.: US 2022/0344239 A1
(43) Pub. Date: Oct. 27, 2022

(54) COOLING ASSEMBLY AND AN ELECTRONIC CIRCUIT MODULE HAVING THE SAME

(71) Applicant: HEWLETT PACKARD ENTERPRISE DEVELOPMENT LP, Houston, TX (US)

(72) Inventors: Harvey J. Lunsman, Chippewa Falls, WI (US); Ernesto Ferrer, Aguadilla, PR (US); Brady Dulian, Chippewa Falls, WI (US); Steven Dean, Chippewa Falls, WI (US)

(21) Appl. No.: 17/240,688

(22) Filed: Apr. 26, 2021

(51) Int. Cl. H01L 23/373; H05K 1/02

(52) U.S. Cl. CPC H01L 23/3733; H01L 23/3737; H05K 1/0203

(57) ABSTRACT

Examples described herein relate to a cooling assembly. In some examples, the cooling assembly includes a cooling component and a thermal gap pad disposed in thermal contact with the cooling component. The thermal gap pad includes thermally conductive fabric that is curved at a plurality of locations along one or both of its length or its breadth, wherein a first side of the thermal gap pad is disposed in thermal contact with the cooling component and a second side of the thermal gap pad is disposable in thermal contact with a heat generating component. Certain examples described herein also relate to an electronic circuit module having the cooling assembly.

### BACKGROUND

Electronic systems generally include one or more circuit assemblies each including one or more electronic circuit modules. An electronic circuit module typically includes several electronic components disposed on a circuit board. These electronic components may generate heat during their operation. In order to minimize any adverse effects of such heat generated by the electronic components, some circuit assemblies include thermal management systems having a cooling assembly to draw the heat away from the electronic components.

### BRIEF DESCRIPTION OF THE DRAWINGS

These and other features, aspects, and advantages of the present specification will become better understood when the following detailed description is read with reference to the accompanying drawings in which like characters represent like parts throughout the drawings, wherein:

FIG. 1A depicts a perspective view of a cooling assembly, in accordance with an example;

FIG. 1B depicts an elevation view of the cooling assembly of FIG. 1A, in accordance with an example;

FIG. 1C depicts an exploded view of the cooling assembly of FIG. 1A, in accordance with an example;

FIG. 2 depicts an elevation view of an electronic circuit module including the cooling assembly of FIG. 1A, in accordance with an example;

FIG. 3 depicts an elevation view of an electronic circuit module including the cooling assembly of FIG. 1A, in accordance with another example;

FIG. 4 depicts a thermally conductive fabric that is used to form a thermal gap pad, in accordance with an example;

FIG. 5A depicts a perspective view of a thermal gap pad, in accordance with an example;

FIG. 5B depicts an elevation view of the thermal gap pad shown in FIG. 5A, in accordance with an example;

FIG. 6A depicts a perspective view of a thermal gap pad, in accordance with an example;

FIG. 6B depicts an elevation view of the thermal gap pad shown in FIG. 6A, in accordance with an example;

FIG. 7 depicts a perspective view of a thermal gap pad, in accordance with another example;

FIG. 8 depicts a perspective view of a thermal gap pad, in accordance with yet another example; and

FIG. 9 depicts a flow chart illustrating a method for assembling a cooling assembly, in accordance with an example.

It is emphasized that, in the drawings, various features are not drawn to scale. In fact, in the drawings, the dimensions of the various features have been arbitrarily increased or reduced for clarity of discussion.

### DETAILED DESCRIPTION

The following detailed description refers to the accompanying drawings. Wherever possible, same reference numbers are used in the drawings and the following description to refer to the same or similar parts. It is to be expressly understood that the drawings are for the purpose of illustration and description only. While several examples are described in this document, modifications, adaptations, and other implementations are possible. Accordingly, the following detailed description does not limit disclosed examples. Instead, the proper scope of the disclosed examples may be defined by the appended claims.

The terminology used herein is for the purpose of describing particular examples and is not intended to be limiting. As used herein, the singular forms “a,” “an,” and “the” are intended to include the plural forms as well, unless the context clearly indicates otherwise. The term “another,” as used herein, is defined as at least a second or more. The term “coupled,” as used herein, is defined as connected, whether directly without any intervening elements or indirectly with at least one intervening element, unless indicated otherwise. For example, two elements may be coupled mechanically, electrically, or communicatively linked through a communication channel, pathway, network, or system. Further, the term “and/or” as used herein refers to and encompasses any and all possible combinations of the associated listed items. It will also be understood that, although the terms first, second, etc. may be used herein to describe various elements, these elements should not be limited by these terms, as these terms are only used to distinguish one element from another unless stated otherwise or the context indicates otherwise. As used herein, the term “includes” means includes but not limited to, the term “including” means including but not limited to.

An object, device, or assembly (which may comprise multiple distinct bodies that are thermally coupled, and may include multiple different materials), is “thermally conductive” if a heat transfer coefficient between two thermal interfaces of the object is 10 W·m⁻²·k⁻¹ or greater at any temperature between 0° C. and 100° C. Alternatively, a body consisting of a continuous piece of a given material is “thermally conductive” if the thermal conductivity (often denoted k, λ, or K) of the material is 1 W·m⁻¹·k⁻¹ or greater at any temperature between 0° C. and 100° C.

Electronic systems including, but not limited to, computers (stationary or portable), servers, storage systems, wireless access points, network switches, routers, docking stations, printers, or scanners, generally include circuit assemblies including one or more electronic circuit modules. An electronic circuit module typically includes several electronic components disposed on a circuit board, such as, a printed circuit board (PCB). Examples of the electronic components may include, but are not limited to, integrated circuit (IC) chips, power supply chips or modules, electronic devices such as capacitors, inductors, resistors, and the like. Examples of the IC chip may be an application-specific integrated circuit (ASIC), a field-programmable gate array (FPGA) chip, a processor chip, a memory chip, a wireless communication module chip, and the like. During operation, these electronic components may generate heat. As will be understood, such heat generated by the electronic components is unwanted and may impact operation of the electronic components. In particular, in certain cases, the heat may cause a physical damage to the electronic components and/or degrade performance of electronic components.

In order to minimize any adverse effects of the heat generated by the electronic components, some circuit assemblies include thermal management systems having a cooling assembly to draw the heat away from the electronic components generating the heat. In some implementations, the cooling assembly may entail use of one or more heatsinks. The heatsinks may be disposed in thermal contact (e.g., in direct physical contact or via thermally conductive materials or adhesives) with the electronic components disposed on the PCB. The heatsinks absorb heat generated by the electronic components and transfer the heat away from the electronic components.

In certain designs of the electronic circuit modules, the electronic components may have varying heights resulting in an uneven topology of top surfaces of the electronic components. In some implementations, the IC chips disposed on the PCB may have different heights. Accordingly, top surfaces of the IC chips may be positioned at different heights. In certain other implementations, even though the IC chips disposed on the PCB may have same heights, the top surfaces of the IC chips may be positioned at different heights due to one or more of design tolerances, soldering imperfections, or variations in applied pressures on the IC chips. Consequently, if a common heatsink (or any other cooling medium, for example, a cold plate) is used for cooling several such electronic components, the common heatsink/cold plate cannot be positioned to maintain thermal contact with top surfaces of all electronic components. In particular, the electronic components with lower heights cannot come in contact with the common heatsink/cold plate. Accordingly, the cooling assembly may not effectively perform cooling of the electronic components of the electronic circuit module.

Further, in some implementations, the cooling assemblies entail use of compressible thermal gap pads (also referred to as thermally conductive pad or thermal interface pad) made from chemical materials, including but not limited to, silicone polymer and thermal medium such as ceramic. The thermal gap pads made from chemical materials are hereinafter referred to as chemical gap pads. The chemical gap pads may be disposed between the electronic components and the heat sinks to fill in air gaps caused by imperfectly flat or smooth surfaces and microscopic irregularities while allowing conduction of heat from the electronic components to the heatsinks. However, such chemical gap pads may have low thermal conductivity resulting in inefficient cooling of the electronic components. Consequently, the electronic components that remain heated (e.g., not properly cooled) may cause conduction of the heat via the substrate of the PCB. Such conduction of the heat via the substrate of the PCB may cause heating of one or more of the rest of the electronic components, for example, a die-to-die heating of the rest of the IC chips. Also, in some instances, the chemical gap pads may lose its thermal conduction properties over a period of time, become hard, or may get damaged leading to inefficient and unreliable cooling of the electronic components. Accordingly, in such instances, the chemical gap pads are required to be replaced. Furthermore, certain other implementations of the cooling assemblies may entail use of heatsinks with precision machined surfaces for exact mating with electronic components with varying heights. However, such precision machined heatsinks are very costly to produce and may not be scalable for mass production.

In accordance with the aspects of the present disclosure, an improved cooling assembly is provided for electronic circuit modules that mitigates one or more challenges noted hereinabove. In some examples, the cooling assembly presented herein may include a cooling component and a thermal gap pad disposed in thermal contact with the cooling component. The thermal gap pad may include a thermally conductive fabric that is curved at a plurality of locations along one or both of its length or its breadth. The thermal gap pad may be disposed such that a first side of the thermal gap pad is attached to the cooling component and a second side of the thermal gap pad is disposable in thermal contact with a heat generating component. The term “heat generating component” as used herein may refer to an electronic component that generates heat during its operation. Non limiting examples of the heat generating component may include IC chips (e.g., ASIC chips, FPGA chips, processor chips, memory chips, or any other type of IC chips), power supply chips or modules, electronic devices such as capacitors, inductors, resistors, or optical converters, such as, active optical cables (AOC) or vertical-cavity surface emitting laser (VCSEL). Further, the term “cooling component” as used herein may refer to a device or component that is used to cool-down the heat generating component by taking the heat away from the heat generating component. Non limiting examples of the cooling component may include a heatsink or a cold plate.

As will be appreciated, the thermal gap pad, in some examples, is a mechanically formed thermal gap pad made of a thermally conductive fabric (e.g., mesh of thermally conductive wires) opposed to the chemically formed thermal gap pad used in traditional cooling systems. The mechanical thermal gap pad, according to some examples, may provide superior thermal conductivity in comparison to the thermal gap pads made from chemical materials (e.g., silicone polymer). Further, the curves or folds formed in in the thermally conductive fabric may cause the thermal gap pad to achieve a spring effect (e.g., a capability to deflect upon application of force and regain original shape after the application of force is removed) and become compliant, reduces thermal contact resistance and thereby providing enhanced thermal contact between the heat generating components and the cooling component. Moreover, the mechanical thermal gap pad, according to some examples, may last longer than the traditionally used chemical gap pads and may be reusable.

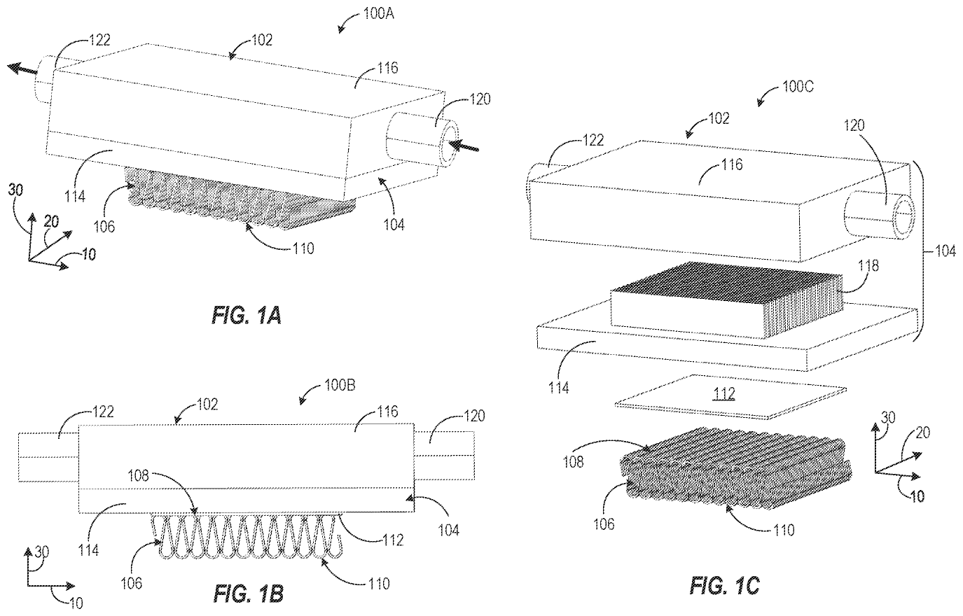

Referring now to drawings, in FIG. 1A, a perspective view 100A of a cooling assembly 102 is presented, in accordance with an example. In the description hereinafter, FIG. 1A is described in conjunction with FIGS. 1B and 1C. In particular, FIG. 1B depicts an elevation view 100B and FIG. 1C depicts an exploded view 100C of the cooling assembly 102 of FIG. 1A, in accordance with an example. In the description hereinafter, FIGS. 1A, 1B, and 1C are referenced concurrently for ease of illustration. In FIGS. 1A-1C, reference numerals 10, 20, and 30 point to an X-axis, a Y-axis, and a Z-axis, respectively. The X-axis 10, the Y-axis 20, and the Z-axis 30 are oriented perpendicular to each other.

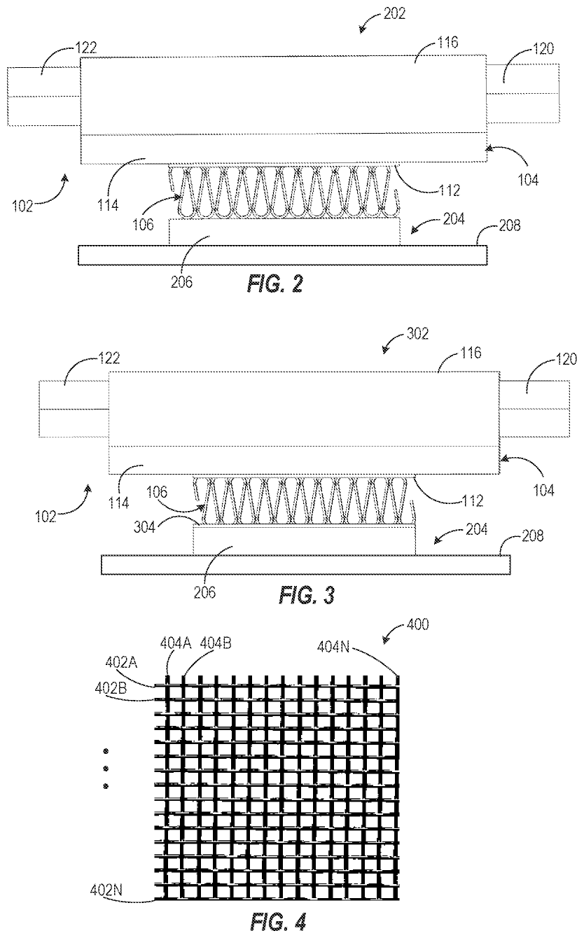

In some examples, the cooling assembly 102 may be disposed in an electronic system, such as, but not limited to, a computer (stationary or portable), a server, a storage system, a wireless access point, a network switch, a router, a docking station, a printer, a scanner, or any other system that entails use of electronic components. These electronic system may include one or more electronic circuit modules (an example electronic circuit modules are shown in FIGS. 2 and 3) including one more electronic components generating heat during their operations. In particular, the cooling assembly 102 may be disposed in thermal contact with the electronic components to absorb heat generated by the electronic components and to transfer the heat away therefrom. The term “thermal contact” as used herein may refer to a contact between two components that allows heat to flow through the contact. Further, the term “disposed in thermal contact” may refer to positioning two components in direct or indirect contact with each other such that heat can flow from one component to the another component.

During operation, the electronic components in the electronic circuit module may generate heat. Accordingly, the term “heat generating component” as used hereinafter may refer to an electronic component that generates heat during its operation. As will be understood, such heat generated by the electronic components is unwanted and may impact operation of the electronic components if not managed effectively. In accordance with the aspects of the present disclosure, the cooling assembly 102 may facilitate effective cooling of one or more heat generating components. The cooling assembly 102 may be disposed in the electronic circuit module over the electronic components, in some examples. For illustration purposes, the cooling assembly 102 presented herein is a liquid cooling system that entails use of a liquid coolant (hereinafter referred to as a coolant) to take heat away from the electronic components. The cooling assembly 102 may also be suitably modified to be an air cooled assembly without limiting the scope of the present disclosure. For ease of illustration, components and devices (e.g., coolant circulation pumps, valves, etc.) used to enable flow of the coolant are not shown in FIGS. 1A-1C and are considered out of the scope of the present disclosure.

In some examples, the cooling assembly 102 presented herein, may include a cooling component 104 and a thermal gap pad 106. The term “cooling component” as used herein may refer to a device or component that is used to cool-down the heat generating component by taking the heat away from the heat generating component. Non limiting examples of the cooling component 104 may include a heatsink or a cold plate. In the example implementation of the cooling assembly 102 depicted in FIGS. 1A-1C, the cooling component 104 is shown to be a cold plate without limiting the scope of the present disclosure. The cooling component 104 may include a body 114 and a housing 116. The body 114 may include heat transfer features 118, for example, fins. Further, the housing 116 may be attached atop the body 114 in a fluid tight manner or may be monolithic to the body 114 (i.e., the body 114 and the housing 116 formed as one single unit). The housing 116 may include a coolant inlet 120 and a coolant outlet 122. The coolant may enter from the coolant inlet 120, absorb heat from the body 114 via the heat transfer features 118, and may exit from the coolant outlet 122.

In some examples, the thermal gap pad 106 may be disposed in thermal contact with the cooling component 104 either via a direct dry contact or via any intermediate thermally conductive material. As depicted in FIGS. 1B-1C, the thermal gap pad 106 may have a first side 108 and a second side 110 that is opposite to the first side 108. In one example, the thermal gap pad 106 is positioned such that the first side 108 of the thermal gap pad 106 is disposed in direct contact with the cooling component 104 in an electronic circuit module. In another example, the thermal gap pad 106 is positioned such that the first side 108 of the thermal gap pad 106 is attached to the cooling component 104 and the second side 110 of the thermal gap pad 106 may be disposed in thermal contact with a heat generating component (see FIGS. 2-3) when the cooling assembly 102 is disposed in the electronic circuit module. For example, in one implementation, the first side 108 of the thermal gap pad 106 may be permanently attached, for example, soldered, to the cooling component 104. In some examples, the first side 108 of the thermal gap pad 106 may be attached to the cooling component 104 via a thermally conductive epoxy, via a thermally conductive adhesive, or via a thermally conductive potting material. For illustration purposes, in FIGS. 1A-1C, the thermal gap pad 106 is shown as attached to the cooling component 104 via a thermally conductive epoxy layer 112. The second side 110 of the thermal gap pad 106 is disposed in thermal contact with the heat generating component either directly (see FIG. 2) or via a thermally conductive material (see FIG. 3).

In some examples, the cooling assembly 102 may be formed by positioning the cooling component 104, the thermal gap pad 106, and the thermally conductive epoxy layer 112 in the order shown in the exploded view 100C shown in FIG. 1C. For example, the thermally conductive epoxy layer 112 may be disposed between the first side 108 of the thermal gap pad 106 and a bottom surface of the cooling component that faces the thermal gap pad 106.

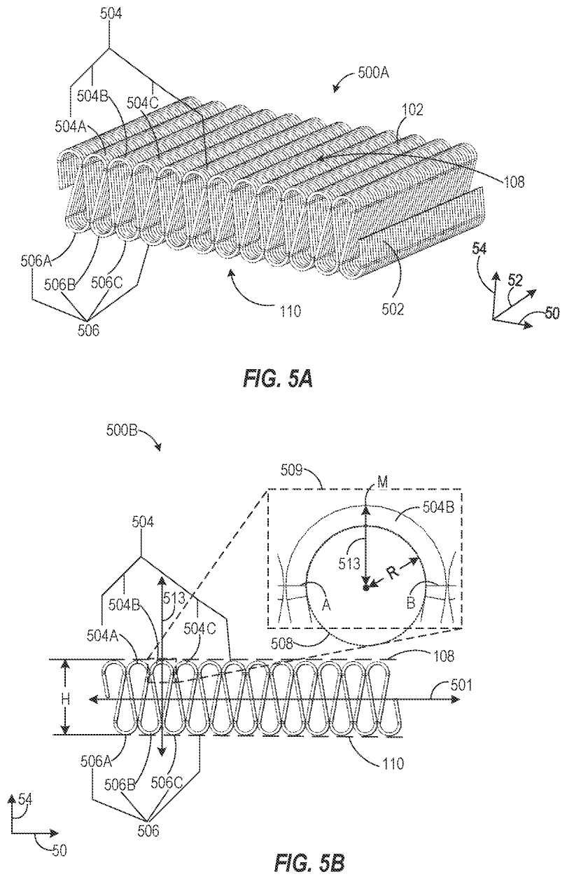

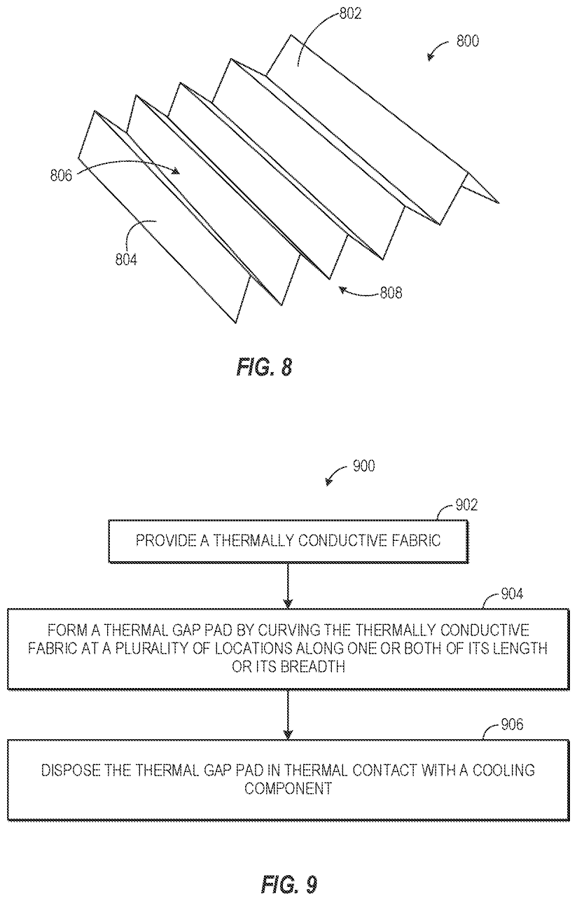

The thermal gap pad 106 may be formed of a thermally conductive fabric (see FIG. 4). Quickly referring now to FIG. 4, a portion of a thermally conductive fabric 400 is presented, in accordance with one example. As depicted, in some examples, the thermally conductive fabric 400 may be a mesh of wires, for example, horizontal wires 402A, 402B, . . . 402N (along a breadth of the thermally conductive fabric 400) and vertical wires 404A, 404B, . . . 404N (along a length of the thermally conductive fabric 400), made of a thermally conductive material. In particular, the thermally conductive fabric may be a mesh of metal wires. In certain other examples, the thermally conductive fabric may be formed by attaching wires or threads of a thermally conductive material in a side-by-side manner using an adhesive. Turning to FIGS. 1A-1C, the thermal gap pad 106 may be formed when the thermally conductive fabric, such as the thermally conductive fabric 400, is curved to at a plurality of locations along one or both of its length or its breadth. For example, shaping the thermally conductive fabric 400 in such a way may cause the thermally conductive fabric 400 to attain a wavy or serpentine shape (see FIGS. 5A, 5B, 6A, 6B, and 7, for example) including a plurality of waves of the thermally conductive fabric 400, a zig-zag shape (see FIG. 8, for example), or a folded shape having one or more folds formed in the thermally conductive fabric. In some examples, an orientation of curves, a size of the curves, and/or density of curves (e.g., number of curves or folds in the thermally conductive fabric per unit length) may be suitably selected to achieve a desired spring effect and thermal performance of the thermal gap pad 106. Additional details regarding the thermal gap pad 106 are described in conjunction with FIGS. 5A, 5B, 6A, 6B, 7, and 8.

Referring now to FIG. 2, an elevation view of an electronic circuit module 202 including the cooling assembly 102 of FIG. 1A is depicted, in accordance with an example. The electronic circuit module 202 may be disposed in an electronic system, such as, but not limited to, a computer (stationary or portable), a server, a storage system, a wireless access point, a network switch, a router, a docking station, a printer, a scanner, or any other system that entails use of electronic components.

As depicted in FIG. 2, in some examples, the electronic circuit module 202 may include a circuit assembly 204 and the cooling assembly 102 disposed in thermal contact with the circuit assembly 204. The circuit assembly 204 may include a circuit board 206 and a heat generating component 208. The circuit board 206 may be a printed circuit board (PCB) that includes several electrical conductive traces (not shown) to electrically interconnect the heat generating component 208 with other components disposed on or outside of the circuit board 206. Non limiting examples of the heat generating component may include IC chips (e.g., ASIC chips, FPGA chips, processor chips, memory chips, or any other type of IC chips), power supply chips or modules, electronic devices such as capacitors, inductors, resistors, or optical converters, such as, AOC or VCSEL. In the example implementation of the circuit assembly 204 of FIG. 2, for illustration purposes, the heat generating component 208 is shown as being an IC chip. Accordingly, the circuit assembly 204 of FIG. 2 may alternatively be referred to as a multi-chip module (MCM). Examples of the IC chips that may be hosted on the circuit board 206 may include, but are not limited to, a processor chip (e.g., a CPU chip), a graphics processing unit chip (e.g., a GPU chip) a microcontroller chip, a memory chip, a power regulator chip, a communication module chip, application-specific integrated circuit (ASIC) chip, a field programmable gate array (FPGA) chip, or any other special purpose or general purpose chip.

It is to be noted that, the electronic circuit module 202 may include various combinations of different types of heat generating components or non-heat generating components, without limiting the scope of the present disclosure. Further, in FIG. 2, while the electronic circuit module 202 is shown to include single heat generating component, e.g., the heat generating component 208, more than one heat generating components may be disposed on the circuit board 206 without limiting the scope of the present disclosure. Further, the scope of the present disclosure is not limited with respect to the number of the heat generating components and the manner in which the heat generating components are laid out on the circuit board 206.

During operation, the heat generating component 208 may generate heat. As will be understood, such heat generated by the heat generating component 208 is unwanted and may impact operation of the heat generating component 208 if not managed effectively. Also, in some examples, the circuit board 206 may host several heat generating components with varying heights resulting in an uneven topology of respective top surfaces. For example, in some implementations, the IC chips disposed on the PCB may have different heights. Accordingly, top surfaces of the IC chips may be positioned at different heights. In certain other implementations, even though the IC chips disposed on the circuit board 206 may have same heights, the top surfaces of the IC chips may be positioned at different heights due to one or more of design tolerances, soldering imperfections, or variations in applied pressures on the IC chips.

Although the circuit assembly 204 of FIG. 2 is shown to include one cooling assembly 102, use of more than one cooling assemblies is also contemplated within the scope of the present disclosure. In accordance with the aspects of the present disclosure, the cooling assembly 102 may facilitate effective cooling of the heat generating component 208 or several heat generating components irrespective of variations in the heights of the heat generating component(s). The cooling assembly 102 may be disposed on the circuit assembly 204 over the heat generating component 208. In the example of FIG. 2, the cooling assembly 102 is disposed on the circuit assembly 204 such that the second side 110 of thermal gap pad 106 is positioned in direct physical contact with the heat generating component 208. Such positioning of the thermal gap pad 106, in certain implementations, may provide direct metal contact with the heat generating component 208 thereby resulting in improved conduction of heat from the heat generating component 208 to the cooling component 104. In certain examples, the thermally conductive epoxy layer 112 may serve as an electrically insulating layer thereby preventing any electrical short-circuit. Further, in some examples, in the cooling assembly 102, the thermal gap pad 106 is positioned such that the first side 108 of the thermal gap pad 106 is disposed in direct contact with the cooling component 104 in an electronic circuit module.

In certain other examples, the second side 110 of the thermal gap pad 106 is disposed in contact with the heat generating component 208 via a thermally conductive adhesive of an electronic circuit module (see FIG. 3). Turning now to FIG. 3, an elevation view of an electronic circuit module 302 including the cooling assembly 102 of FIG. 1A is depicted, in accordance with another example. The electronic circuit module 302 is representative of one example of the electronic circuit module 202 of FIG. 2 and include several components that are described in conjunction with FIGS. 1A-1C and 2, details of which are not repeated herein for the sake of brevity. For example, the electronic circuit module 302 may also include the cooling assembly 102 and the circuit assembly 204. In particular, the cooling assembly 102 may be disposed in thermal contact with the heat generating component 208 via thermally conductive adhesive layer 304. For example, cooling assembly 102 may be positioned such that the second side 110 of the thermal gap pad 106 is placed in thermal contact with the heat generating component 208 via the thermally conductive adhesive layer 304. In such an implementation, the thermally conductive adhesive layer 304 may provide either permanent or temporary (e.g., removable or detachable) thermal coupling of the thermal gap pad 106 with the heat generating component 208. In some examples, the thermally conductive adhesive layer 304 may include electrically insulating material. Examples of thermally conductive material used to form the thermally conductive adhesive layer 304 may include, but are not limited to, silicon based thermally conductive adhesives or polyurethane based thermally conductive adhesives.

Moving now to FIGS. 5A and 5B (referenced concurrently hereinafter), a perspective view 500A and an elevation view 500B of the thermal gap pad 106 are respectively depicted, in accordance with an example. In FIGS. 5A and 5B, reference numerals 50, 52, and 54 point to an X-axis, a Y-axis, and a Z-axis, respectively, of the thermal gap pad 106. Accordingly, a dimension along the X-axis 50, the Y-axis 52, and the Z-axis 54 are referred to as a length, breadth (i.e., width), and height, respectively. Further, in some examples, an imaginary line passing along a length of a thermal gap pad and parallel to a first side (e.g., the side facing the cooling component 104) and a second side (e.g., the side facing the heat generating component 208) is hereinafter referred to as an axis of the thermal gap pad. For example, as depicted in FIG. 5B, an imaginary line passing along a length of the thermal gap pad 106 and parallel to the first side 108 and the second side 110 is hereinafter referred to as an axis 501 of the thermal gap pad 106 (hereinafter referred to as a pad axis 501).

The example thermal gap pad 106 depicted in FIG. 5A may be formed by forming a plurality of opposite facing curves in the thermally conductive fabric 502 so that top edges of the curves define the first side 108 and the second side 110 of the thermal gap pad 106. In some examples, the term ‘curve’ as used herein may refer to a portion of the thermally conductive fabric that is bent to form an arc or an angle at a first side or at a second side (opposite to the first side) of the thermal gap pad. Reference numerals 504A, 504B, and 504C point to some of the many curves formed on the first side 108 of the thermal gap pad 106 and hereinafter referred to as first curves 504A, 504B, and 504C. All of the first curves 504A-5040 and the rest of the curves formed on the first side 108 of the thermal gap pad 106 are hereinafter collectively referred to as first curves 504. Further, reference numerals 506A, 506B, and 506C point to some of the many curves formed on the second side 110 of the thermal gap pad 106 and hereinafter referred to as second curves 506A, 506B, and 506C. All of the second curves 506A-506C and the rest of the curves formed on the second side 110 of the thermal gap pad 106 are hereinafter collectively referred to as second curves 506. As will be understood, formation of the first curves 504 and the second curves 506 may cause the thermally conductive fabric 502 to have a plurality of waves. The first curves 504 and the second curves 506 may be formed by alternatingly folding the thermally conductive fabric 502 in opposite directions at a predefined height (H). In some examples, the first curves 504 and the second curves 506 may be formed by pressing the thermally conductive fabric 502 between molds having ridges and valleys.

One of the curves, for example, the first curve 504B is depicted in an enlarged view 509. Hereinafter, certain parameters/features of the curve 504B are described in detail. The rest of the curves 504 and 506 may also have similar features. As depicted in the enlarged view 509, the curve 504B may begin from a location ‘A’ and end at location ‘B’. A distance from the location ‘A’ to the location ‘B’ on the thermally conductive fabric 502 may represent a length of the curve (hereinafter referred to as a curve length). Further, a location ‘M’ represents a middle point (i.e., a location on the curve 504B in the middle of the curve length of the curve 504B and hereinafter referred to as a middle point ‘M’) of the curve 504B. In some examples, a size of a given curve, e.g., the curve 504B, may be represented as a radius R of an imaginary circle 508 that is centrally aligned to the given curve. Further, an imaginary line passing through the imaginary circle 508 and the middle point ‘M’ of the curve 504B is referred to as a curve orientation direction 513. In some examples, the rest of the curves 504 and 506 may also have the same curve orientation direction as that of the curve 504B. The example thermal gap pad 106 depicted in FIG. 5A-5B may be formed such that the curve orientation directions of the curves 504 and 506 are orthogonal to the pad axis 501. In particular, in the thermal gap pad 106, the curve orientation direction 513 is orthogonal to the pad axis 501. The thermal gap pad 106 having the curve orientation directions orthogonal to the pad axis 501 is also alternatively referred to as a non-angular gap pad.

Moreover, in some examples, the size (e.g., radius) of the curves 504, 506, the breadth and/or the length of the thermally conductive fabric 502 may be selectively chosen depending on an area of a top surface of the heat generating component 208. A number of curves per unit length of the thermal gap pad 106 may be referred to as a density of the thermal gap pad 106. In some examples, the curves 504 and 506 may be made sharper (e.g., see FIGS. 7-8, for example) to increase the density of the thermal gap pad 106. Moreover, one or both of the height H and the density of the thermal gap pad 106 may be suitably designed to achieve a desired spring effect and thermal performance. In certain examples, the thermal gap pad 106 may be formed to have higher density to enhance the spring effect, resulting in higher contact forces between the thermal gap pad 106 and the heat generating component 208 (shown in FIGS. 2 and 3) when disposed on the circuit assembly 204. Further, in some examples, with increase in the density of the thermal gap pad 106 the thermal performance of the thermal gap pad 106 may be improved as the increase in the density results in increased contact points between the thermal gap pad 106 and the heat generating component 208. In some examples, the parameters such as one or more of the height H and the density of the thermal gap pad 106 may be suitably controlled to achieve the desired thermal performance and spring effect.

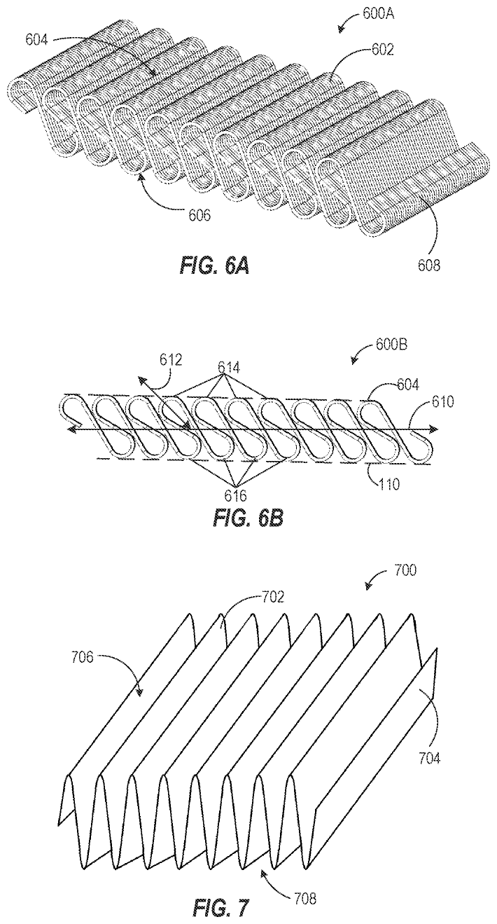

In certain examples, a thermal gap pad may be formed such that a curve orientation direction of one or more of the curves may be non-orthogonal to the axis the thermal gap pad (see FIG. 6A-6B). In other words, the curves formed in the thermally conductive fabric may be angled with respect to a pad axis. Turning now to FIGS. 6A and 6B, a perspective view 600A and an elevation view 600B of a thermal gap pad 602 are respectively depicted, in accordance with an example. FIGS. 6A and 6B will be referenced concurrently hereinafter. The thermal gap pad 602 may be representative of one example of the thermal gap pad 106 shown in earlier drawings and includes several curves formed alternatively on a first side 604 and a second side 606. In comparison to the thermal gap pad 106, in the thermal gap pad 602, a curve orientation direction 612 of one or more of the curves 614 (formed on the first side 604) or curves 616 (formed on the second side 606) may be non-orthogonal (i.e., angled) to a pad axis 610 of the thermal gap pad 602 resulting in angled waves of a thermally conductive fabric 608. The thermal gap pad 602 having the curve orientation directions non-orthogonal to the pad axis 610 of the thermal gap pad 602 is also alternatively referred to as an angular gap pad. In certain examples, shaping the thermally conductive fabric 608 with curve orientation directions non-orthogonal to the pad axis 610 may enhance the spring effect in the thermal gap pad 602.

The thermally conductive fabric may be folded in several other shapes such as but not limited to a wavy shape (see FIG. 7) or a zig-zag shape (see FIG. 8) to form a thermal gap pad. FIG. 7 depicts a perspective view 700 of a thermal gap pad 702, in accordance with an example. The thermal gap pad 702 may be representative of one example of the thermal gap pad 106 and is formed using a thermally conductive fabric 704 and includes several sharp curves formed alternatively on a first side 706 and a second side 708 resulting in a wavy shaped thermally conductive fabric 704. Although the thermal gap pad 702 is depicted as being non-angular gap pad, in certain other examples, the thermal gap pad 702 may also be designed to be an angular gap pad.

FIG. 8 depicts a perspective view 800 of a thermal gap pad 802, in accordance with an example. The thermal gap pad 802 may be representative of one example of the thermal gap pad 106 and is formed using a thermally conductive fabric 804 and includes several angular curves formed alternatively on a first side 806 and a second side 808 resulting in a zig-zag shaped thermally conductive fabric 804. Although the thermal gap pad 802 is depicted as being a non-angular gap pad, in certain other examples, the thermal gap pad 802 may also be designed to be an angular gap pad. Moreover, in certain examples, in a thermal gap pad, the thermally conductive fabric that is curved at a plurality of locations may form a folded shape including one or more folds formed in the thermally conductive fabric along one or both of the length or the breadth of the thermally conductive fabric.

Referring now to FIG. 9, a method 900 of assembling a cooling assembly, such as, the cooling assembly 102 is presented, in accordance with an example. Although the method 900 is described in conjunction with the cooling assembly 102 described in FIGS. 1A-1C for ease of illustration, the method 900 should not be construed to be limited to specifics of the cooling assembly 102, for example, shape of the thermally conductive fabric, the number of curves, and/or the density of the thermal gap pad 106. At block 902, a thermally conductive fabric (e.g., the thermally conductive fabric 400) may be provided. At block 904, the thermally conductive fabric may be curved at a plurality of locations along one or both of its length or its breadth to form a thermal gap pad. In particular, a plurality of curves may be formed along the length and/or the breadth of the thermally conductive fabric. In some examples, shaping the thermally conductive fabric as indicated in block 904 may result in a thermal gap pad having a wavy pattern (shown in FIGS. 5A, 5B, 6A, 6B, and 7), a zig-zag pattern (shown in FIG. 8), a shape with a plurality of folds both along its length or breadth, or having another shape achievable by folding the thermally conductive fabric at multiple locations. In some examples, the curves in the thermally conductive fabric may be formed by pressing the thermally conductive fabric 502 between molds having ridges and valleys. Further, at block 906, the thermal gap pad may be disposed in thermal contact with the cooling component, such as, the cooling component 104. Disposing the thermal gap pad 106 in thermal contact with the cooling component 104 may include performing one or more of: disposing the first side 108 of the thermal gap pad 106 in direct physical contact (e.g., in direct dry contact) with the cooling component 104, soldering the first side 108 of the thermal gap pad 106 to the cooling component 104, attaching the thermal gap pad 106 to the cooling component 104 via a thermally conductive epoxy (e.g., the thermally conductive epoxy layer 112), or attaching the thermal gap pad 106 to the cooling component 104 via a thermally conductive adhesive. Further, in certain examples, a thermally conductive adhesive layer for example, the thermally conductive adhesive layer 304 may be applied on the second side 100 of the thermal gap pad 106.

As will be appreciated, the thermal gap pad (e.g., the thermal gap pad 106, 602, 702, 802), in some examples, is a mechanically formed thermal gap pad made of a thermally conductive fabric opposed to the chemically formed thermal gap pad used in traditional cooling systems. The mechanical thermal gap pad (e.g., the thermal gap pad 106, 602, 702, 802), according to some examples, may provide superior thermal conductivity in comparison to the thermal gap pads made from chemical materials (e.g., silicone polymer). Further, the curves or folds formed in in the thermally conductive fabric may cause the thermal gap pad to achieve a spring effect (e.g., a capability to deflect upon application of force and regain original shape after the application of force is removed) and become compliant, thereby providing enhanced thermal contact between the heat generating components and the cooling component. Moreover, the mechanical thermal gap pad, according to some examples, may last longer than the traditionally used chemical gap pads and may be reusable.

While certain implementations have been shown and described above, various changes in from and details may be made. For example, some features and/or functions that have been described in relation to one implementation and/or process may be related to other implementations. In other words, processes, features, components, and/or properties described in relation to one implementation may be useful in other implementations. Furthermore, it should be appreciated that the systems and methods described herein may include various combinations and/or sub-combinations of the components and/or features of the different implementations described. Moreover, method blocks described in various methods may be performed in series, parallel, or a combination thereof. Further, the method blocks may as well be performed in a different order than depicted in flow diagrams.

Further, in the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

1. A cooling assembly of an apparatus, comprising:
a cooling component; and
a thermal gap pad in thermal contact with the cooling component, wherein the thermal gap pad comprises a mesh of thermally conductive fabric that is curved at a plurality of locations along one or both of its length or its breadth, wherein the mesh includes a first set of length-wise wires and a second set of breath-wise wires, and wherein a first side of the thermal gap pad is in thermal contact with the cooling component and a second side of the thermal gap pad is in thermal contact with a heat generating component of the apparatus.

2. (canceled)

3. The cooling assembly of claim 1, wherein the mesh of thermally conductive fabric comprises a mesh of metal wires.

4. The cooling assembly of claim 1, wherein the mesh of thermally conductive fabric comprises a plurality of metal wires attached to each other in a side-by-side manner.

5. The cooling assembly of claim 1, wherein the first side of the thermal gap pad is permanently attached to the cooling component.

6. The cooling assembly of claim 1, wherein the first side of the thermal gap pad is soldered to the cooling component, attached to the cooling component via a thermally conductive epoxy, or attached to the cooling component via a thermally conductive adhesive.

7. The cooling assembly of claim 1, wherein the second side of the thermal gap pad is opposite to the first side and is in contact with the heat generating component via a thermally conductive adhesive.

8. The cooling assembly of claim 7, wherein the thermally conductive adhesive comprises electrically insulating material.

9. The cooling assembly of claim 1, wherein the mesh of thermally conductive fabric forms a wavy shape comprising a plurality of waves of the thermally conductive fabric.

10. The cooling assembly of claim 1, wherein the mesh of thermally conductive fabric forms a zig-zag shape based on the curves at the plurality of locations.

11. The cooling assembly of claim 1, wherein the mesh of thermally conductive fabric forms a folded shape comprising one or more folds formed in the thermally conductive fabric along one or both of the length or the breadth of the thermally conductive fabric.

12. The cooling assembly of claim 1, wherein the mesh of thermally conductive fabric forms curves at the plurality of locations, wherein the curves are oriented non-orthogonal to an axis of the thermal gap pad.

13. The cooling assembly of claim 1, wherein the mesh of thermally conductive fabric forms curves at the plurality of locations, wherein the curves are oriented orthogonal to an axis of the thermal gap pad.

14. An electronic circuit module, comprising:
a circuit assembly comprising a heat generating component on a circuit board; and
a cooling assembly in thermal contact with the heat generating component, the cooling assembly comprising:
a cold plate; and
a thermal gap pad attached to the cold plate, wherein the thermal gap pad comprises a mesh of thermally conductive fabric that is shaped into a wavy pattern comprising a plurality of waves of the thermally conductive fabric, wherein the mesh includes a first set of length-wise wires and a second set of breath-wise wires, and wherein a first side of the thermal gap pad is in thermal contact to the cold plate and a second side of the thermal gap pad is in thermal contact with the heat generating component.

15. The electronic circuit module of claim 14, wherein the heat generating component comprises an electronic component.

16. The electronic circuit module of claim 15, wherein the electronic component is an integrated circuit chip.

17. A method of assembling a cooling assembly of an apparatus, the method comprising:
incorporating a mesh of thermally conductive fabric into the cooling assembly, wherein the mesh includes a first set of length-wise wires and a second set of breath-wise wires;
forming a thermal gap pad by curving the thermally conductive fabric at a plurality of locations along one or both of its length or its breadth; and
disposing the thermal gap pad in thermal contact with a cooling component such that a first side of the thermal gap pad is in thermal contact with the cooling component and a second side of the thermal gap pad is in thermal contact with a heat generating component of the apparatus.

18. The method of claim 17, wherein disposing the thermal gap pad in thermal contact with the cooling component comprises one or more of: soldering the first side of the thermal gap pad to the cooling component, attaching the thermal gap pad to the cooling component via a thermally conductive epoxy, and attaching the thermal gap pad to the cooling component via a thermally conductive adhesive.

19. The method of claim 17, further comprising applying a thermally conductive adhesive on the second side of the thermal gap pad.

20. (canceled)

21. The cooling assembly of claim 1, wherein the heat generating component comprises an integrated circuit chip.

22. The electronic circuit module of claim 14, wherein the first side of the thermal gap pad is soldered to the cooling component, attached to the cooling component via a thermally conductive epoxy, or attached to the cooling component via a thermally conductive adhesive.
